(19) United States
(12) Patent Application Publication
(10) Pub. No.: US 2025/0275385 A1
(43) Pub. Date: Aug. 28, 2025

(54) Light Emitting Display Device

(71) Applicant: LG Display Co., Ltd., Seoul (KR)

(72) Inventors: Hye Min Hwang, Paju-si (KR); Beom Gon Jo, Paju-si (KR); Min Ki Kim, Paju-si (KR)

(21) Appl. No.: 18/989,937

(22) Filed: Dec. 20, 2024

(30) Foreign Application Priority Data
Feb. 27, 2024 (KR) 10-2024-0028395

(51) Int. Cl. H10K 59/126; H10K 59/121; H10K 59/80

(52) U.S. Cl. CPC H10K 59/126; H10K 59/1213; H10K 59/80518

(57) ABSTRACT

A light emitting display device is disclosed. The light emitting display device includes a substrate including a plurality of sub-pixels, driving circuits respectively provided at the plurality of sub-pixels, an insulating layer provided on the driving circuits, reflective electrodes respectively provided at the plurality of sub-pixels in the insulating layer, a trench provided in the insulating layer among the plurality of sub-pixels, a light shielding material layer filling the trench, and a light emitting element provided on the insulating layer.

### CROSS-REFERENCE TO RELATED APPLICATION

This application claims the benefit of Republic of Korea Patent Application No. 10-2024-0028395 filed on Feb. 27, 2024, which is hereby incorporated by reference in its entirety.

### BACKGROUND

### Field of Technology

The present disclosure relates to a light emitting display device configured to prevent or at least reduce light generated from a light emitting element in the display device from influencing a lower circuit.

### Discussion of the Related Art

A display device displays an image to the user. For this function, the display device may include light emitting elements.

Each of the light emitting elements may be connected to a lower circuit including a transistor provided on a substrate, for driving thereof.

Recent display devices are used for various applications. As one example of such applications, a method in which a display device is disposed adjacent to the eyes of the user has been proposed. In this case, pixels should be disposed in a small area corresponding to the eye and, as such, high resolution is required. For clear display, high luminance is also required. To this end, research on development of a display device having high resolution and high luminance is being conducted.

### SUMMARY

Accordingly, the present disclosure is directed to a light emitting display device that substantially obviates one or more problems due to limitations and disadvantages of the related art.

An object of the present disclosure is to prevent light generated from a light emitting element from influencing a lower driving circuit.

Another object of the present disclosure is to provide a light emitting display device having an ultra-high resolution structure in which sub-pixels are densely disposed in a limited area, the light emitting display device including a structure capable of preventing light emitted from individual light emitting elements from being transmitted to sub-pixels disposed adjacent thereto.

Another object of the present disclosure is to provide a light emitting display device having an ultra-high resolution structure, the light emitting display device being configured to enhance optical reliability of transistors driven by a very small current.

The light emitting display device according to an embodiment of the present disclosure may reduce power consumption, and may have effects of high efficiency, high luminance, and high color reproduction while enabling low-power driving. Thus, environmental/social/governance (ESG) goals may be achieved.

To achieve these objects and other advantages and in accordance with the purpose of the disclosure, as embodied and broadly described herein, a light emitting display device includes a substrate including a plurality of sub-pixels, driving circuits respectively provided at the plurality of sub-pixels, an insulating layer provided on the driving circuits, reflective electrodes respectively provided at the plurality of sub-pixels in the insulating layer, a trench provided in the insulating layer among the plurality of sub-pixels, a light shielding material layer filling the trench, and a light emitting element provided on the insulating layer.

### BRIEF DESCRIPTION OF THE DRAWINGS

The accompanying drawings, which are included to provide a further understanding of the disclosure and are incorporated in and constitute a part of this application, illustrate embodiment(s) of the disclosure and along with the description serve to explain the principle of the disclosure. In the drawings:

FIG. 1 is a diagram schematically showing a light emitting display device according to an embodiment of the present disclosure;

FIG. 2 is a circuit diagram showing a circuit of a sub-pixel of FIG. 1 according to an embodiment of the present disclosure;

FIG. 3 is a plan view showing a light emitting display device according to a first embodiment of the present disclosure;

FIG. 4 is a cross-sectional view taken along line I-I′ in FIG. 3 according to an embodiment of the present disclosure;

FIGS. 5A and 5B are sectional views showing different forms of a light emitting element of FIG. 3, respectively according to an embodiment of the present disclosure;

FIG. 6 is a graph depicting I-V characteristics in a structure of a light emitting display device in which there is no light shielding material layer in a trench;

FIG. 7 is a cross-sectional view showing a light emitting display device according to a second embodiment of the present disclosure;

FIG. 8 is a cross-sectional view showing a light emitting display device according to a third embodiment of the present disclosure;

FIG. 9 is a cross-sectional view showing a light emitting display device according to a fourth embodiment of the present disclosure; and

FIG. 10 is a cross-sectional view showing a light emitting display device according to a fifth embodiment of the present disclosure.

### DETAILED DESCRIPTION

Reference will now be made in detail to preferred embodiments of the disclosure, examples of which are illustrated in the accompanying drawings. Wherever possible, the same reference numbers will be used throughout the drawings to refer to the same or like parts. In the following description of the disclosure, detailed descriptions of known functions and configurations incorporated herein will be omitted when the same may obscure the subject matter of the disclosure. In addition, the names of elements used in the following description are selected in consideration of clarity of description of the disclosure, and may differ from the names of elements of actual products.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt %, or when the p-type material is present in an amount of less than 30 wt %, the layer is considered to be a “doped” layer.

Further, the term “undoped” refers to layers that are not “doped”. For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In this present disclosure, an electroluminescence (EL) spectrum can be calculated by multiplying (a) a photoluminescence (PL) spectrum, which applies the inherent characteristics of an emissive material such as a dopant material or a host material included in an organic emission layer, by (b) an outcoupling or emittance spectrum curve, which is determined by the structure and optical characteristics of an organic light-emitting element including the thicknesses of organic layers such as, for example, an electron transport layer.

In the specification, a stack means a unit structure including a hole transport layer, a common layer including an electron transport layer, and an emission layer disposed between the hole transport layer and the electron transport layer. In the common layer, a hole injection layer, an electron blocking layer, a hole blocking layer, an electron injection layer, etc. may be further included. In addition, other organic layers or inorganic layers may be further included in the stack in accordance with a structure or design of a light emitting element.

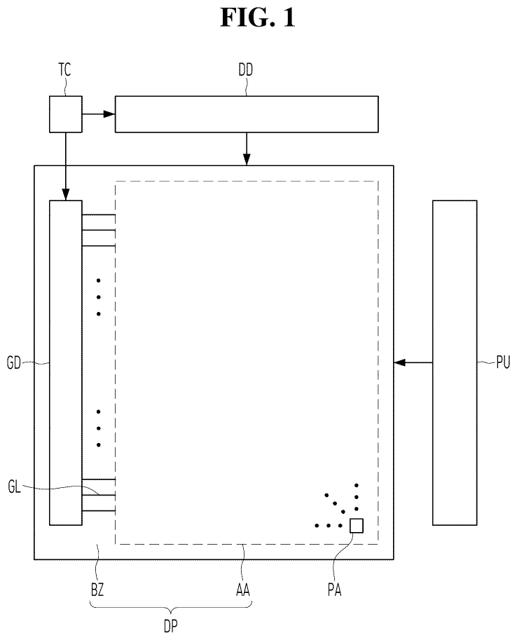

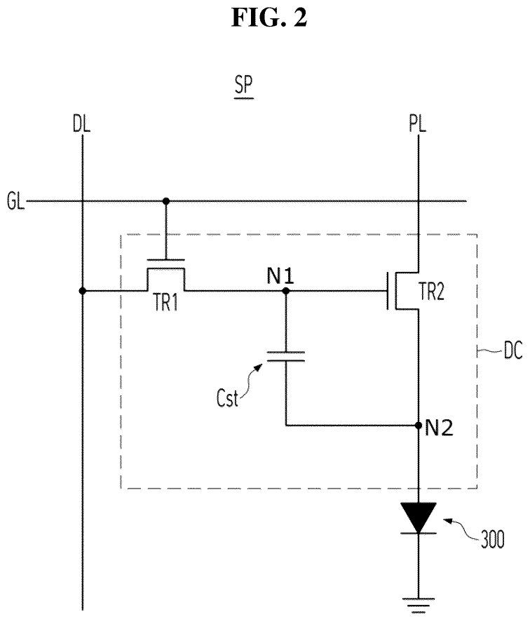

FIG. 1 is a diagram schematically showing a light emitting display device according to an embodiment of the present disclosure. FIG. 2 is a circuit diagram showing a circuit of a sub-pixel of FIG. 1 according to an embodiment of the present disclosure.

As shown in FIGS. 1 and 2, the light emitting display device according to the embodiment of the present disclosure may include a display panel DP. The display panel DP may generate an image to be provided to the user. For example, a plurality of pixel areas PA may be disposed in the display panel DP. Each pixel area PA may render various colors. For example, each pixel area PA may include a plurality of sub-pixels SP. Various signals may be applied to each sub-pixel SP through signal lines GL, DL, and PL. For example, the signal lines GL, DL, and PL may include gate lines GL each configured to apply a gate signal, data lines DL each configured to apply a data signal, and a power voltage supply lines PL each configured to supply a power supply voltage.

The gate lines GL may be electrically connected to a gate driver GD. The data lines DL may be electrically connected to a data driver DD. The gate driver GD and the data driver DD may be controlled by a timing controller TC. For example, the gate driver GD may receive clock signals, reset signals, and a start signal from the timing controller TC, and the data driver DD may receive digital video data and a source timing signal from the timing controller TC. The power voltage supply lines PL may be electrically connected to a power unit PU.

The display panel DP may include an active area AA in which the pixel areas PA are disposed, and a bezel area BZ disposed outside the active area AA. The bezel area BZ may be disposed outside the pixel areas PA. For example, the active area AA may be surrounded by the bezel area BZ. The gate driver GD, the data driver DD, the timing controller TC, and the power unit PU may be disposed outside the active area AA. For example, respective signal lines GL, DL, and PL may include areas disposed on the bezel area BZ. At least one of the gate driver GD, the data driver DD, the timing controller TC, or the power unit PU may be disposed on the bezel area BZ of the display panel DP. For example, the light emitting display device according to the embodiment of the present disclosure may be a gate-in-panel (GIP) type light emitting display device in which the gate driver GD is directly formed on a substrate in the bezel area BZ. In this case, a GIP may include a plurality of transistors and a plurality of capacitors, and the transistors and capacitors included in the GIP may be manufactured using the same process or substantially the same process as that of transistors disposed on the substrate in the active area AA.

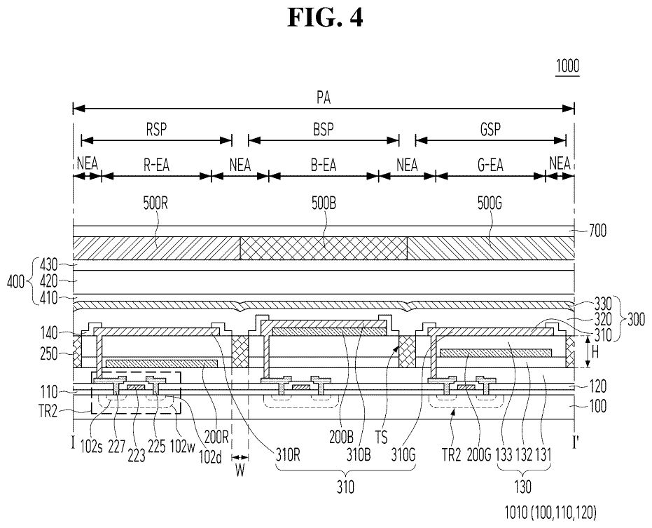

As shown in FIG. 2, each sub-pixel SP may emit light representing a particular color in accordance with signals applied thereto through signal lines GL, DL, and PL. For example, a driving circuit DC, which is electrically connected to a light emitting element (cf. “300” in FIG. 4), may be disposed in each sub-pixel SP. The display panel DP may include a substrate (cf. “100” in FIG. 4) configured to support the driving circuit DC of each sub-pixel SP and the light emitting element 300.

Operation of the light emitting element 300 disposed in each sub-pixel SP may be controlled by signals applied to the light emitting element 300 through the signal lines GL, DL, and PL.

For example, the driving circuit DC of each sub-pixel SP may include a first transistor TR1, a second transistor TR2, and a storage capacitor Cst.

A first source/drain electrode (for example, a drain electrode) of the first transistor TR1 is electrically connected to the data line DL, and a second source/drain electrode (for example, a source electrode) of the first transistor TR1 is connected to a gate electrode of the second transistor TR2. Here, a connection node between the first transistor TR1 and the second transistor TR2 is referred to as a first node N1.

The first transistor TR1 transmits, to the first node N1, a data signal supplied through the data line DL in response to a scan signal supplied through the gate line GL.

The storage capacitor Cst is electrically connected between the first node N1 and a second node N2. The storage capacitor Cst charges a voltage applied to the first node N1 therein.

A first source/drain electrode (for example, a drain electrode) of the second transistor TR2 receives a high-level drive voltage EVDD through the power voltage supply line PL, and a second source/drain electrode (for example, a source electrode) is electrically connected to an anode of the light emitting element 300. The second transistor TR2 may control an amount of a drive current flowing through the light emitting element 300, corresponding to a voltage applied to the gate electrode thereof.

The first transistor TR1 of each sub-pixel SP may transmit, to the second transistor TR2 of the same sub-pixel SP, a data signal supplied to the data line DL in accordance with a gate signal applied to the gate line GL. For example, the first transistor TR1 of each sub-pixel SP may function as a switching transistor, and the second transistor TR2 of each sub-pixel SP may function as a driving transistor.

For example, the driving circuit DC of each sub-pixel SP may supply, to the light emitting element 300 of the same sub-pixel SP, a drive current corresponding to a data signal in accordance with a gate signal. The drive current supplied by the drive circuit DC of each sub-pixel SP may be maintained for one frame by the storage capacitor Cst of the same sub-pixel SP.

Hereinafter, a detailed configuration of the light emitting display device according to the present disclosure will be described with reference to the accompanying drawings.

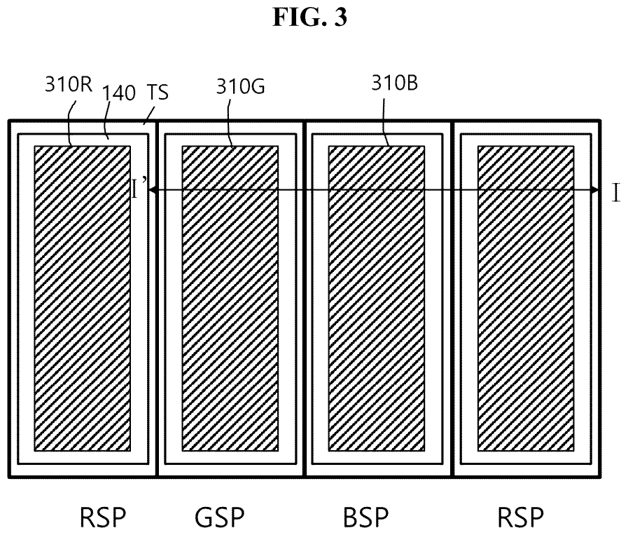

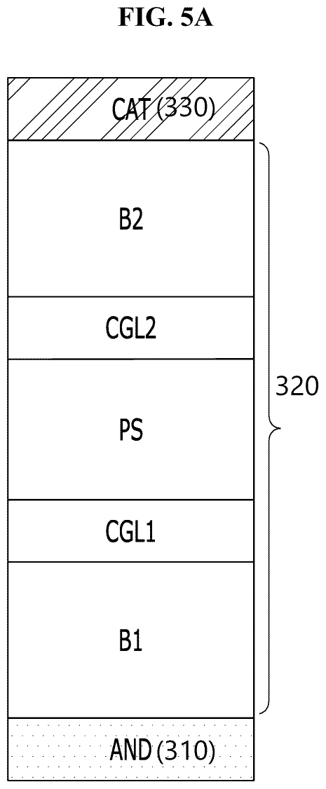

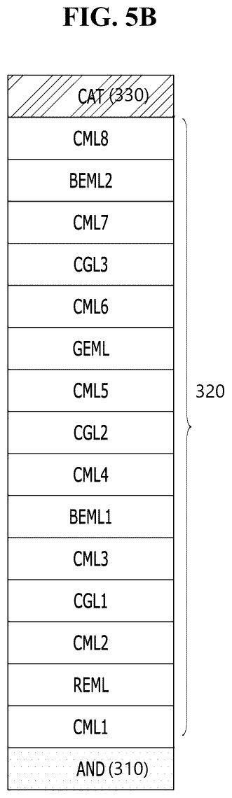

FIG. 3 is a plan view showing a light emitting display device according to a first embodiment of the present disclosure. FIG. 4 is a cross-sectional view taken along line I-I′ in FIG. 3 according to an embodiment of the present disclosure. FIGS. 5A and 5B are sectional views showing different forms of a light emitting element of FIG. 3, respectively according to an embodiment of the present disclosure.

As shown in FIGS. 3 to 5B, a light emitting display device 1000 according to an embodiment of the present disclosure includes a substrate 100 including a plurality of sub-pixels RSP, BSP, and GSP, a driving circuit (cf. “DC” in FIG. 2) included in each of the plurality of sub-pixels RSP, BSP, and GSP while including transistors (cf. “TR1” and “TR2” in FIG. 2) and a storage capacitor (cf. “Cst” in FIG. 2), and an insulating layer 130 provided on the driving circuit DC.

As shown in FIGS. 3 and 4, a red sub-pixel RSP, a blue sub-pixel BSP, and a green sub-pixel GSP may be disposed adjacent to one another.

In respective sub-pixels RSP, BSP, and GSP, emission areas R-EA, B-EA, and G-EA are defined in areas corresponding to anodes 310 (310R, 310B, and 310G), respectively, and areas among the emission areas R-EA, B-EA, and G-EA are defined as non-emission areas NEA, respectively.

FIG. 4 shows a cross-section taken along line I-I′ in FIG. 3. In FIG. 4, connection relations of the anodes 310 (310R, 310B, and 310G) and transistors TR2 functioning as driving transistors in the driving circuits DC of respective sub-pixels RSP, GSP, and BSP are shown. As shown in FIG. 2, each sub-pixel may further include a first transistor TR1 functioning as a switching transistor and a storage capacitor Cst, in addition to the second transistor TR2.

In addition, the light emitting display device 1000 according to the embodiment of the present disclosure may include reflective electrodes 200R, 200B, and 200G respectively included in the plurality of sub-pixels RSP, GSP, and BSP while being disposed in the insulating layer 130, trenches TS respectively disposed in the insulating layer 130 among the plurality of sub-pixels RSP, GSP, and BSP, a light-shielding material layer 250 filling the trenches TS, and a light emitting element 300 disposed on the insulating layer 130.

Meanwhile, the light emitting element 300 is constituted by the anodes 310 (310R, 310B, and 310G), an intermediate layer 320, and a cathode 330.

The anodes 310 (310R, 310B, and 310G) in the configuration of the light emitting element 300 are provided at respective sub-pixels RSP, GSP, and BSP such that adjacent ones thereof in the sub-pixels RSP, GSP, and BSP are separated from each other, through exposure and development processes using a mask. Accordingly, the anodes 310 (310R, 310B, and 310G) operate individually in respective sub-pixels RSP, GSP, and BSP. The anodes 310 may be distinguished from one another in the red, green, and blue sub-pixels RSP, GSP, and BSP, as a first anode 310R, a second anode 310G, and a third anode 310B, respectively.

The intermediate layer 320 in the configuration of the light emitting element 300 may be configured through inclusion of at least one functional layer and at least one emission layer, and may be formed in common in an active area AA including the plurality of sub-pixels RSP, GSP, and BSP. For example, the intermediate layer 320 may be formed using a common mask having an opening in at least the active area AA. The intermediate layer 320 may emit white light.

In respective sub-pixels RSP, BSP, and GSP, the reflective electrodes 200R, 200G, and 200B disposed under the light emitting element 300 configured to emit white light are adjusted to have different vertical phases and, as such, to have resonance distances corresponding to red, blue, and green to be rendered in respective sub-pixels RSP, BSP, and GSP.

That is, the reflective electrodes 200R, 200G, and 200B may include first to third reflective electrodes 200R, 200G, and 200B having different vertical phases, respectively, and may be included in the red sub-pixel RSP, the green sub-pixel GSP, and the blue sub-Pixel BSP, respectively.

The reflective electrodes 200R, 200G, and 200B of respective sub-pixels RSP, GSP, and BSP may include a material having high reflectance. For example, the reflective electrodes 200 of respective sub-pixels RSP, GSP, and BSP may include a reflective metal such as aluminum (Al) or silver (Ag) or an alloy thereof. In the display device according to the embodiment of the present disclosure, in addition to a facing electrode structure constituted by the anodes 310 (310R, 310G, and 310B) and the cathode 330, the separate reflective electrodes 200R, 200G, and 200B are added to respective emission areas R-EA, G-EA, and B-EA, and the vertical phases of the reflective electrodes 200R, 200G, and 200B are disposed at positions where optimum micro-cavity effects according to respective wavelengths in the sub-pixels RSP, GSP, and BSP are generated. Accordingly, an enhancement in light extraction efficiency may be achieved.

In respective sub-pixels RSP, GSP, and BSP, light reflected by the cathode 330 in the light emitting element 300 may be again reflected by the reflective electrodes 200R, 200G, and 200B.

For example, the red sub-pixel RSP corresponds to a longest wavelength one of red, green, and blue and, as such, may have a longest vertical resonance distance between the first reflective electrode 200R and the cathode 330, and the blue sub-pixel BSP corresponds to a shortest wavelength one of red, green, and blue and, as such, may have a shortest vertical resonance distance between the third reflective electrode 200B and the cathode 330. The third reflective electrode 200B may directly contact the third anode 310B.

The light emitting display device 1000 according to each embodiment of the present disclosure is a near-eye display device configured to be used in a state of being adjacent to the eyes of a viewer. That is, the sub-pixels are densely disposed in the limited area of the substrate 100. In the near-eye display device, the configuration of a light emitting display device including a substrate is disposed near the eyes of the viewer in the form of eyeglasses or a head-up display device and, as such, may express virtual reality (VR) or augmented reality (AR). Accordingly, in the near-eye display device, the size of the substrate should be as small as a few inches, and a plurality of sub-pixels should be densely disposed in the limited area of the substrate, for image display, and, as such, the size of each sub-pixel is very small, as compared to the configuration of a display device configured to be used at a certain distance from the eyes of a viewer, as in a portable phone, a television, or the like. Accordingly, in the small-size sub-pixels, respective anodes thereof should have a small size, and low-current driving should be carried out. Even in low-current driving, the sub-pixels should also achieve high-luminance expression.

Referring to FIG. 4, in the light emitting display device according to the embodiment of the present disclosure, widths of the emission areas R-EA, B-EA, and G-EA of respective sub-pixels are several μm or less and widths of the non-emission areas NEA among adjacent ones of the sub-pixels are 1 μm or less, and as such, the size of each sub-pixel is very small. Accordingly, light emission may be possible using even a small drive current.

In the light emitting display device according to the embodiment of the present disclosure, the light shielding material layer 250 is provided at the trenches TS disposed among the sub-pixels in order to prevent influence caused by generation of a photoelectric current by internal light transmitted from the light emitting element 300 to a lower side thereof in a high-resolution structure drivable by a small current. That is, in the light emitting element 300, light is emitted from the intermediate layer 320 to not only upper and lower sides thereof, but also to lateral sides thereof. In a structure not provided with the light shielding material layer 250, leakage of light may occur when light emitted from a particular sub-pixel is directed to a transistor of a sub-pixel adjacent to the particular sub-pixel, and the leaked light may generate a photoelectric current in the transistor, thereby resulting in a phenomenon in which the adjacent sub-pixel is pseudo-driven. In this case, it may be difficult to achieve clear display of the particular sub-pixel.

The reflective electrodes 200R, 200G, and 200B are provided under the light emitting element 300 and, as such, may block light directly transmitted from the sub-pixels RSP, GSP, and BSP corresponding thereto to a lower side thereof. The light shielding material layer 250 disposed in the trenches TS among the sub-pixels RSP, GSP, and BSP may block lateral light transmitted from the light emitting element 300 at one of the sub-pixels RSP, GSP, and BSP to an adjacent one of the sub-pixels RSP, GSP, and BSP. Accordingly, it may be possible to achieve clear driving of the individual sub-pixels RSP, GSP, and BSP without generation of leakage current between adjacent ones of the sub-pixels RSP, GSP, and BSP. In this case, optical reliability of the driving circuits may be enhanced. In addition, since generation of leakage current between adjacent ones of the sub-pixels is prevented during low-grayscale driving, there is an advantage in that clear display may be achieved.

The intermediate layer 320 may be formed without being divided on a sub-pixel basis, for omission of an ultra-fine mask and convenience of processes. In this case, the trench TS is provided among the sub-pixels RSP, GSP, and BSP in order to prevent or at least reduce generation of lateral leakage current between adjacent ones of the sub-pixels RSP, GSP, and BSP through the intermediate layer 320. Separation of the intermediate layer 320 between adjacent ones of the sub-pixels RSP, GSP, and BSP may be obtained through the trench TS. That is, the intermediate layer 320 disposed at the sub-pixels RSP, GSP, and BSP may be partially separated between adjacent ones of the sub-pixels RSP, GSP, and BSP through the trench TS.

In the light emitting display device according to each embodiment of the present disclosure, the light shielding material layer 250 fills the trench TS disposed between adjacent ones of the sub-pixels RSP, GSP, and BSP and, as such, it may be possible to prevent or at least reduce light emitted from the light emitting element of at least one of particular sub-pixels RSP, GSP, and BSP from laterally leaking to an adjacent sub-pixel.

For example, the light shielding material layer 250 may be a light shielding organic material. It is preferred that the light shielding material layer 250 be an insulating material in order to have an insulating effect from the reflective electrodes 200R, 200G, and 200B adjacent thereto.

The light shielding material layer 250 may be configured through inclusion of a light shielding material. For example, the light shielding material layer may be constituted by a polyimide component including a black pigment or a polyamide component including a black pigment.

The light shielding material layer 250, which fills the trench TS, may fill a full depth of the trench TS, as shown in FIG. 4. However, the light emitting display device according to each embodiment of the present disclosure is not limited to the above-described condition. The light shielding material layer 250 may have a height H smaller than the depth of the trench TS.

For example, a lower surface of the trench TS may be disposed at a level lower than an upper surface of the first reflective electrode 200R having a lowest phase, and an upper surface of the light shielding material layer 250 may be disposed at a level higher than an upper surface of the second reflective electrode 200G, and, as such, the light shielding material layer 250 may block light transmitted from the light emitting element 300 at one of the sub-pixels to a lower side of an adjacent one of the sub-pixels.

The driving circuit DC of each of the sub-pixels RSP, GSP, and BSP and the light emitting element 300 may be disposed on the substrate 100.

The substrate 100 may be constituted by various materials.

In the light emitting display device according to the embodiment of the present disclosure, the substrate 100 may be a wafer formed of a semiconductor material such as silicon.

At least a part of the driving circuit DC disposed in each of the sub-pixels RSP, GSP, and BSP, for example, an active layer functioning as a semiconductor of each transistor, may be formed in the substrate 100. Accordingly, in the light emitting display device according to the embodiment of the present disclosure, density of the driving circuits DC formed in respective sub-pixels SP may be enhanced. In addition, in the light emitting display device according to the embodiment of the present disclosure, the process of forming the driving circuits DC of respective sub-pixels SP may be simplified.

The second transistor TR2 of each sub-pixel SP may generate the drive current according to the data signal. For example, the second transistor TR2 of each sub-pixel SP may function as a driving transistor. The second transistor TR2 of each sub-pixel SP may include a well region 102w, a first source/drain region 102d, a second source/drain region 102s, a gate electrode 223, a first source/drain electrode 225, and a second source/drain electrode 227. For example, in each of the sub-pixels RSP, GSP, and BSP, the gate electrode 223 of the second transistor TR2 may be electrically connected to one of the source/drain electrodes of the first transistor TR1, the second source/drain electrode 227 of the second transistor TR2 may be electrically connected to a power voltage supply line PL corresponding to the same sub-pixel SP, and the first source/drain electrode 225 of the second transistor TR2 may be connected to a corresponding one of the anodes 310 (310R, 310G, and 310B).

The well region 102w and the first and second source/drain regions 102d and 102s may be formed in the substrate 100. For example, the well region 102w and the first and second source/drain regions 102d and 102s may be formed through a process of doping with conductive impurities. The well region 102w and the first and second source/drain regions 102d and 102s may include conductive impurities of different types, respectively. For example, the well region 102w may include an N-type impurity, and the first and second source/drain regions 102d and 102s may include a P-type impurity. The first and second source/drain regions 102d and 102s may be formed in the well region 102w. For example, a portion of the well region 102w disposed between the first and second source/drain regions 102d and 102s may function as a channel region in the second transistor TR2.

Meanwhile, although not shown in FIG. 4, the first transistor TR1 may be formed in the same process as that of the second transistor TR2. Accordingly, the first transistor TR1 may include a well region disposed in the substrate 100, and source/drain regions disposed in the well region, and the well region of the substrate 100 may be used as an active layer.

Thus, in the light emitting display device according to the embodiment of the present disclosure, a wafer including silicon may be used as the substrate 100, and the well region of the substrate 100 may be used as an active layer, and, as such, it may be possible to omit a process of forming a separate active layer. Accordingly, there are advantages in terms of integration and process simplification suitable for realization of fine sub-pixels.

The first and second transistors TR1 and TR2 may be implemented to have different characteristics through doping of the well region and the source/drain regions in the substrate 100 with different impurities. Alternatively, the first and second transistors TR1 and TR2 may be implemented to have different characteristics using different shapes of the well region and the source/drain regions such that widths/lengths of the channel regions of the first and second transistors TR1 and TR2 are different from each other.

The gate electrode 223 may be disposed on the substrate 100. The gate electrode 223 may be disposed between the first source/drain region 102d and the second source/drain region 102s. For example, the gate electrode 223 may overlap with the portion of the well region 102w functioning as a channel region. The gate electrode 223 may include a conductive material. For example, the gate electrode 223 may include a metal such as aluminum (Al), chromium (Cr), copper (Cu), molybdenum (Mo), titanium (Ti), or tungsten (W). The gate electrode 223 may be spaced apart from the substrate 100. The gate electrode 223 may be insulated through inclusion of an insulating layer 110 between the gate electrode 223 and the substrate 100. For example, the portion of the well region 102w functioning as a channel region may have electrical conductivity corresponding to a voltage applied to the gate electrode 223.

The first and second source/drain electrodes 225 and 227 may include a conductive material. For example, the first and second source/drain electrodes 225 and 227 may include a metal such as aluminum (Al), chromium (Cr), copper (Cu), molybdenum (Mo), titanium (Ti), or tungsten (W). The first and second source/drain electrodes 225 and 227 may include a material different from that of the gate electrode 223. The first and second source/drain electrodes 225 and 227 may be disposed on a layer different from that of the gate electrode 223. The first source/drain electrodes 225 may be electrically connected to the first source/drain region 102d, and the second source/drain electrodes 227 may be connected to the second source/drain region 102s. The first source/drain electrode 225 may be insulated from the gate electrode 223.

The storage capacitor Cst of each sub-pixel SP may maintain a voltage applied to the gate electrode 223 of the second transistor TR2 of the same sub-pixel SP for one frame. For example, the storage capacitor Cst of each sub-pixel SP may be electrically connected to the gate electrode 223 and the second source/drain electrode 227 of the second transistor TR2 in the same sub-pixel SP. The storage capacitor Cst of each sub-pixel SP may have a stack structure of capacitor electrodes. For example, the storage capacitor Cst of each sub-pixel SP may include a first capacitor electrode electrically connected to the gate electrode 223 of the same sub-pixel SP, and a second capacitor electrode electrically connected to the second source/drain electrode 227 of the same sub-pixel SP. The storage capacitor Cst of each sub-pixel SP may be formed using a process of forming the first transistor TR1 and the second transistor TR2 in the same sub-pixel SP. For example, the first capacitor electrode of each sub-pixel SP may be disposed on the same layer as that of the gate electrode 223 of the same sub-pixel SP, and the second capacitor electrode of each sub-pixel SP may be disposed on the same layer as that of the second source/drain electrode 227 of the same sub-pixel SP or may be formed to be integrated with the second source/drain electrode 227 of the same sub-pixel SP. Accordingly, in the light emitting display device according to the embodiment of the present disclosure, efficiency of the process of forming the driving circuits DC in respective sub-pixels SP may be enhanced.

A plurality of insulating layers 110, 120, and 130 for reducing or preventing unnecessary electrical connection may be disposed on the substrate 100. For example, a gate insulating layer 110, an interlayer insulating layer 120, a planarization layer 130, and fences 140 may be disposed on the substrate 100.

The gate insulating layer 110 may be disposed on the substrate 100. The gate insulating layer 110 may be disposed between the gate electrode 223 and the substrate 100 and, as such, the gate electrode 223 may be insulated from the well region 102w of the substrate 100 by the gate insulating layer 110.

For example, in each of the sub-pixels RSP, GSP, and BSP, an upper surface of the substrate 100 facing the gate electrode 223 of each transistor may be covered by the gate insulating layer 110. The gate insulating layer 110 may directly contact the upper surface of the substrate 100. The gate electrode 223 of each of the sub-pixels RSP, GSP, and BSP may be disposed on the gate insulating layer 110. The gate insulating layer 110 may include an insulating material. For example, the gate insulating layer 110 may include an inorganic insulating material such as silicon oxide (SiOx) or silicon nitride (SiNx).

The interlayer insulating layer 120 may be disposed on the gate insulating layer 110. The first and second source/drain electrodes 225 and 227 of each of the sub-pixels RSP, GSP, and BSP may be insulated from the gate electrode 223 of the same one of the sub-pixels RSP, GSP, and BSP by the interlayer insulating layer 120. For example, the gate electrode 223 of each of the sub-pixels RSP, GSP, and BSP may be covered by the interlayer insulating layer 120. The first and second source/drain electrodes 225 and 227 of each of the sub-pixels RSP, GSP, and BSP may be disposed on the interlayer insulating layer 120. The interlayer insulating layer 120 may include an insulating material. For example, the interlayer insulating layer 120 may include an inorganic insulating material.

The planarization layer 130 may be disposed on the interlayer insulating layer 120. The planarization layer 130 may remove a step formed by the driving circuit DC of each sub-pixel SP.

In addition, the planarization layer 130 may include a first insulating layer 131 used as a formation surface for the first reflective electrode 200R while covering the transistors TR1 and TR2, a second insulating layer 132 used as a formation surface for the second reflective electrode 200G while covering the first reflective electrode 200R, and a third insulating layer 133 used as a formation surface for the third reflective electrode 200B while covering the second reflective electrode 200G.

The first and second source/drain electrodes 225 and 227 of each of the transistors TR1 and TR2 in each of the sub-pixels RSP, GSP, and BSP may be covered by the first insulating layer 131.

An upper surface of each of the first to third insulating layers 131, 132, and 133 is flat and, as such, the first to third reflective electrodes 200R, 200G, and 200B may be disposed on the flat upper surfaces of the first to third insulating layers 131, 132, and 133, respectively.

The first to third insulating layers 131, 132, and 133 may include an organic insulating material or an inorganic insulating material. The first to third insulating layers 131, 132, and 133 may be formed of an organic insulating material or may be formed through stacking of a plurality of inorganic insulating layers in order to achieve easy planarization. A part of the first to third insulating layers 131, 132, and 133 may be constituted by an organic insulating material, and the remaining part of the first to third insulating layers 131, 132, and 133 may be constituted by an inorganic insulating material.

The light emitting element 300 may be provided at each of the sub-pixels RSP, GSP, and BSP and, as such, light of a color having a grayscale corresponding to the same sub-pixel is emitted in accordance with the driving circuit DC of the same sub-pixel. Two facing electrodes of the light emitting element 300, that is, each anode 310 and the cathode 330, may include conductive materials, respectively.

Transmittance of the anodes 310 (310R, 310B, and 310G) may be greater than that of the cathode 330. For example, each of the anodes 310 (310R, 310B, and 310G) may be a transparent electrode constituted by a transparent conductive material such as indium tin oxide (ITO), indium zinc oxide (IZO), or the like, and the cathode 330 may be a transparent reflective electrode formed of a metal or a metal alloy including at least one of silver (Ag), magnesium (Mg), or ytterbium (Yb) while being formed to have a small thickness. The work function of the cathode 330 may be smaller than that of each anode 310.

In the light emitting display device according to the embodiment of the present disclosure, the reflective electrodes 200R, 200G, and 200B are provided under the anodes 310 (310R, 310B, and 310G), respectively, and, as such, light generated from the intermediate layer 320 may be emitted upwards and downwards, and may then repeat resonance according to reflection and re-reflection between the reflective electrodes 200R, 200G, and 200B and the cathode 330. Finally, light exits through the cathode 330.

In the light emitting display device according to the embodiment of the present disclosure, among light of different colors generated by the intermediate layer 320, red light may be amplified by a vertical distance between the first reflective electrode 200R and the first anode 310R disposed at the red sub-pixel RSP. In addition, among light of different colors generated by the intermediate layer 320, green light may be amplified by a vertical distance between the second reflective electrode 200G and the second anode 310G disposed at the green sub-pixel GSP. In addition, among light of different colors generated by the intermediate layer 320, blue light may be amplified by a vertical distance between the third reflective electrode 200B and the third anode 310B disposed in the blue emission area B-EA at the blue sub-pixel BSP. In the light emitting display device according to the embodiment of the present disclosure, each of the sub-pixels RSP, GSP, and BSP may emit light representing a color different from that of another one of the sub-pixels RSP, GSP, and BSP adjacent thereto using a micro-cavity structure. Accordingly, in the light emitting display device according to the embodiment of the present disclosure, color reproducibility of light emitted from each of the sub-pixels RSP, GSP, and BSP may be enhanced.

The intermediate layer 320 may be formed through stacking of one or more stacks each including a hole injection layer HIL, a hole transport layer HTL, an emission layer EML, an electron transport layer ETL, and an electron injection layer EIL between the anodes 310 and the cathode 330. In this case, the emission layer EML may be an emission layer configured to emit white light.

In the case in which white light is emitted from the intermediate layer 320, color filters 500R, 500B, and 500G may be provided over the light emitting element 300, corresponding to the sub-pixels RSP, BSP, and GSP, respectively, and, as such, colors of the sub-pixels RSP, BSP, and GSP may be represented.

As another form, the intermediate layer 320 may have a configuration including a plurality of stacks B1, PS, and B2 between an anode AND (310) and a cathode CAT (330), as shown in FIG. 5A. In this case, light finally exiting through the cathode CAT (330) may be white light in accordance with a combination of colors emitted from the plurality of stacks B1, PS, and B2.

Each of the stacks B1, PS, and B2 may include at least one hole transport layer HTL, at least one emission layer EML, and at least one electron transport layer ETL. The stacks B1, PS, and B2 may be divided from one another by charge generation layers CGL1 and CGL2, respectively. Each of the charge generation layers CGL1 and CGL2 may include an n-type charge generation layer configured to generate electrons and to transfer the generated electrons to a lower stack adjacent thereto, and a p-type charge generation layer configured to generate holes and to transfer the generated holes to an upper stack adjacent thereto.

In the case of FIG. 5A, each of the first stack B1 adjacent to the anode AND (310) and the third stack B2 adjacent to the cathode CAT (330) may include a blue emission layer, and the blue emission layer may include at least one of a fluorescent material or a phosphorescent material.

The second stack PS between the first and third stacks B1 and B2 may be configured through inclusion of an emission layer of a longer wavelength than that of blue. The second stack PS may include a plurality of phosphorescent emission layers. If necessary, one of the first stack B1 and the third stack B2 may be omitted and, as such, the intermediate layer 320 may be configured through inclusion of a blue stack BS configured to emit blue, a phosphorescent emission stack PS including a phosphorescent emission layer, and a charge generation layer CGL between the blue stack BS and the phosphorescent emission stack PS.

In this case, light exiting from the light emitting display device 1000 is based on a color emitted from the intermediate layer 320. Accordingly, the second stack PS may also include a red emission layer and a green emission layer adjacent to each other in order to enable expression of pure colors from individual light emitting elements.

The cathode 330 may be formed in a deposition process, and may be provided in the active area AA while having a smaller thickness than that of the intermediate layer 320.

FIG. 5B shows another form of the intermediate layer 320 of the light emitting element 300 including a plurality of stacks. The intermediate layer 320 of FIG. 5B is different from that of FIG. 5A in terms of disposition of emission layers while including an increased number of stacks. In the light emitting element according to FIG. 5B, the intermediate layer 320 disposed between the anode AND (310) and the cathode CAT (330) is configured through inclusion of a first common layer CML1, a red emission layer REML, a second common layer CML2, a first charge generation layer CGL1, a third common layer CML3, a first blue emission layer BEML1, a fourth common layer CML4, a second charge generation layer CGL2, a fifth common layer CML5, a green emission layer GEML, a sixth common layer CML6, a third charge generation layer CGL3, a seventh common layer CML7, a second blue emission layer BEML2, and an eighth common layer CML8.

Each of stacks divided from one another by the charge generation layers CGL1, CGL2, and CGL3 includes a single emission layer. The single emission layer may be disposed at an optimum distance corresponding to a color to be emitted and, as such, emission expression of pure colors to be displayed by respective sub-pixels RSP, GSP, and BSP may be more reliably possible.

In the intermediate layer 320, each of the first common layer CML1, the third common layer CML3, the fifth common layer CML5, and the seventh common layer CML7 may include a hole transport layer, and each of the second common layer CML2, the fourth common layer CML4, the sixth common layer CML6, and the eighth common layer CML8 may include an electron transport layer.

The first common layer CML1 adjacent to the anode AND may further include a hole injection layer, and the eighth common layer CML8 adjacent to the cathode CAT may further include an electron injection layer.

The plurality of sub-pixels RSP, BSP, and GSP provided at the substrate 100 may include a red sub-pixel RSP, a blue sub-pixel BSP, and a green sub-pixel GSP.

Although the intermediate layers of the light emitting elements shown in FIGS. 5A and 5B are shown as including three stacks and four stacks, respectively, the light emitting display device according to each embodiment of the present disclosure is not limited thereto. Such an intermediate layer may include a single stack, two stacks, or five or more stacks.

Meanwhile, in the light emitting display device according to each embodiment of the present disclosure, the intermediate layer 320 may be formed in the entirety of the active area AA in a deposition process. In this case, it is unnecessary to provide a deposition mask requiring openings for respective sub-pixels of high resolution in a process of forming the intermediate layer 320 and the cathode 330. Accordingly, there is an advantage in that production yield is increased in accordance with omission of a fine deposition mask.

In the light emitting display device according to the embodiment of the present disclosure, it may be possible to disconnect continuity between adjacent ones of sub-pixels RSP, BSP, and GSP by a trench TS provided between the adjacent ones of the sub-pixels RSP, BSP, and GSP, as shown in FIGS. 3 and 4, even when no ultra-fine deposition mask is provided in formation of the intermediate layer 320.

As shown in FIG. 3, the trench TS may have a shape surrounding the anodes 310 (310R, 310B, and 310G) of respective sub-pixels RSP, GSP, and BSP when viewed in plan.

In addition, in the light emitting display device according to the embodiment of the present disclosure, as shown in FIG. 4, the light shielding material layer 250, which has a height H, fills an interior of the trench TS. For separation of the intermediate layer 320 among the sub-pixels RSP, GSP, and BSP according to structural steps between areas in which the anodes 310 (310R, 310B, and 310G) overlap with respective sub-pixels RSP, GSP, and BSP and an area of the trench TS, an upper surface of the light shielding material layer 250 is disposed below the fences 140. In the case of FIG. 4, a side portion of each fence 140 may partially contact the upper surface of the light shielding material layer 250.

The intermediate layer 320 may be disconnected at a portion thereof by the trench TS in an area having a relatively low step. Accordingly, the intermediate layer 320 may be partially separated on a sub-pixel basis and, as such, generation of leakage current between adjacent ones of the sub-pixels may be reduced or prevented.

The intermediate layer 320 may generate light of a luminance corresponding to a voltage difference between each anode 310 and the cathode 330.

The fences 140 may be disposed on the planarization layer 130. The fences 140 may insulate the anode 310 of each of the sub-pixels RSP, GSP, and BSP from the anode 310 of another sub-pixel SP adjacent to the former sub-pixel SP. For example, edges of the anodes 310 disposed in respective sub-pixels RSP, GSP, and BSP may be covered by the fences 140. The fences 140 may include an insulating material. Each fence 140 may be a linear insulating layer having a predetermined thickness. For example, the fences 140 may include an inorganic insulating material.

The fences 140 may expose portions of the anodes 310 disposed in respective sub-pixels SP. For example, the fences 140 may define emission areas R-EA, B-EA, and G-EA in respective sub-pixels SP. Areas disposed among the emission areas R-EA, B-EA, and G-EA may be defined as non-emission areas NEA. For example, the fences 140 may be disposed in the non-emission areas NEA. Portions of the anodes 310 disposed in the emission areas R-EA, B-EA, and G-EA of respective sub-pixels SP may directly contact an upper surface of the planarization layer 130. The intermediate layer 320 and the cathode 330 of the sub-pixels RSP, BSP, and GSP may be stacked on the portions of the anodes 310 (310R, 310B, and 310G) exposed by the fences 140. For example, the intermediate layer 320 may directly contact the anodes 310 and the cathode 330 in the emission areas R-EA, B-EA, and G-EA of respective sub-pixels RSP, BSP, and GSP. Accordingly, in the light emitting display device according to the embodiment of the present disclosure, luminance deviations according to generation positions of light emitted from the emission areas R-EA, B-EA, and G-EA of respective sub-pixels RSP, BSP, and GSP may be prevented.

The reflective electrodes 200R, 200B, and 200G may be disposed between the driving circuits DC of the sub-pixels RSP, BSP, and GSP and the anodes 310, respectively. The reflective electrodes 200R, 200B, and 200G of the sub-pixels RSP, BSP, and GSP may overlap with the emission areas R-EA, B-EA, and G-EA of the sub-pixels RSP, BSP, and GSP, respectively.

An encapsulation layer 400 may be disposed on the light emitting element 300 in the sub-pixels RSP, BSP, and GSP. The encapsulation layer 400 may prevent damage of the light emitting element 300 caused by external moisture and impact. The encapsulation layer 400 may have a multilayer structure. For example, the encapsulation layer 400 may include a first encapsulation layer 410, a second encapsulation layer 420, and a third encapsulation layer 430 sequentially stacked in this order. Each of the first encapsulation layer 410, the second encapsulation layer 420, and the third encapsulation layer may include an insulating material. The second encapsulation layer 420 may include a material different from that of the first encapsulation layer 410 and the third encapsulation layer 430. For example, each of the first encapsulation layer 410 and the third encapsulation layer 430 is an inorganic encapsulation layer including an inorganic insulating material, and the second encapsulation layer 420 may be an organic encapsulation layer including an organic insulating material. Accordingly, in the light emitting display device according to the embodiment of the present disclosure, damage of the light emitting element 300 caused by external moisture and impact may be effectively prevented. Steps formed by the light emitting element 300 at the sub-pixels RSP, GSP, and BSP may be removed by the second encapsulation layer 420. For example, an upper surface of the encapsulation layer 400 facing the substrate 100 may be flat. The second encapsulation layer 420 may have a greater thickness than those of the first encapsulation layer 410 and the third encapsulation layer 430.

Color filters 500R, 500B, and 500G may be disposed on the encapsulation layer 400. The color filters 500R, 500B, and 500G may overlap with the emission areas R-EA, B-EA, and G-EA, respectively. For example, the color filters 500R, 500B, and 500G may include a red color filter 500R overlapping with the red emission area R-EA, a blue color filter 500B overlapping with the blue emission area B-EA, and a green color filter 500G overlapping with the green emission area G-EA.

Each of the color filters 500R, 500B, and 500G may have a greater size than that of a corresponding one of the emission areas R-EA, B-EA, and G-EA. For example, a boundary between adjacent ones of the color filters 500R, 500B, and 500G may overlap with the trench TS. Accordingly, in the light emitting display device according to the embodiment of the present disclosure, light emitted from the light emitting element 300 at respective sub-pixels RSP, GSP, and BSP may surely pass through the color filters 500R, 500B, and 500G of respective sub-pixels RSP, GSP, and BSP. Accordingly, in the light emitting display device according to the embodiment of the present disclosure, a light leakage phenomenon may be reduced or prevented. In addition, in the light emitting display device according to the embodiment of the present disclosure, color reproducibility may be enhanced.

A protective layer 700 may be disposed on the color filters 500R, 500B, and 500G. The protective layer 700 may prevent or at least reduce damage of the color filters 500R, 500B, and 500G caused by external impact and moisture. The protective layer 700 may include an insulating material. For example, the protective layer 700 may include at least one of an inorganic insulating material or an organic insulating material. The protective layer 700 may have a multilayer structure. For example, the protective layer 700 may have a structure in which an inorganic protective layer constituted by an inorganic insulating material is formed on an organic protective layer constituted by an organic insulating material. Accordingly, in the light emitting display device according to the embodiment of the present disclosure, damage of the color filters 500R, 500B, and 500G caused by external impact and moisture may be prevented.

Meanwhile, in the configuration of FIG. 4, a configuration including not only the substrate 100, the gate insulating layer 110, and the interlayer insulating layer 120, but also the gate electrode 223 between the gate insulating layer 110 and the interlayer insulating layer 120, is referred to as an element substrate 1010. In the following embodiments, a connector TRC of each second transistor may be provided on the element substrate 1010.

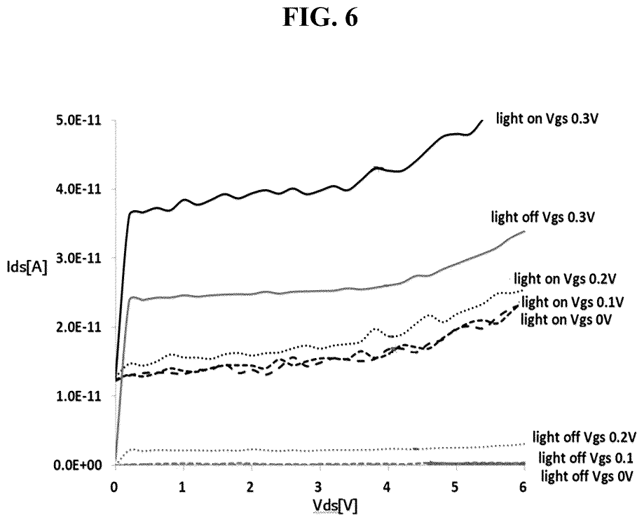

FIG. 6 is a graph depicting I-V characteristics in a structure of a light emitting display device in which there is no light shielding material layer in a trench.

An experiment of FIG. 6 was carried out for a structure having the same or substantially same structure shown in FIG. 4, except that there is no light shielding material layer in the trench.

A current Ids between a drain electrode and a source electrode (the second source/drain electrode 225) of the second transistor TR2 was evaluated by increasing a voltage Vds in accordance with an on/off state of the light emitting element 300 of the light emitting display device while changing a voltage Vgs between a gate electrode and the source electrode of the second transistor TR to 0V, 0.1V, 0.2V, and 0.3V.

Referring to FIG. 6, it is seen that generation of a photoelectric current occurs in each of the cases in which the voltage Vgs between the gate electrode and the source electrode of the second transistor TR2 is 0V, 0.1V, 0.2V, and 0.3V, respectively, in an on state of the light emitting element, as compared to an off state of the light emitting element. That is, it is seen that a high-resolution structure is influenced by generation of a photoelectric current even in a minute voltage variation.

The light emitting element according to each embodiment of the present disclosure may eliminate a problem of influence thereof on driving circuits of adjacent sub-pixels by providing a trench between the adjacent sub-pixels, and filling the trench with a light shielding material layer.

In the light emitting display device in which there is no light shielding material layer in the trench, different from the structure shown in FIG. 4, leakage light spreading radially during light emission of a particular sub-pixel may generate a photoelectric current at the transistor of another sub-pixel adjacent to the particular sub-pixel when the leakage current is directed to the transistor of the adjacent sub-pixel.

Through prevention of such a phenomenon, the light emitting display device according to the embodiment of the present disclosure may prevent or at least reduce leakage of light to the sub-pixel adjacent to the particular sub-pixel during light emission of the particular sub-pixel, and may prevent malfunction of the driving circuit of the adjacent sub-pixel by lateral leakage light and, as such, may enhance optical reliability of the driving circuit.

Hereinafter, a light emitting display device according to another embodiment of the present disclosure will be described.

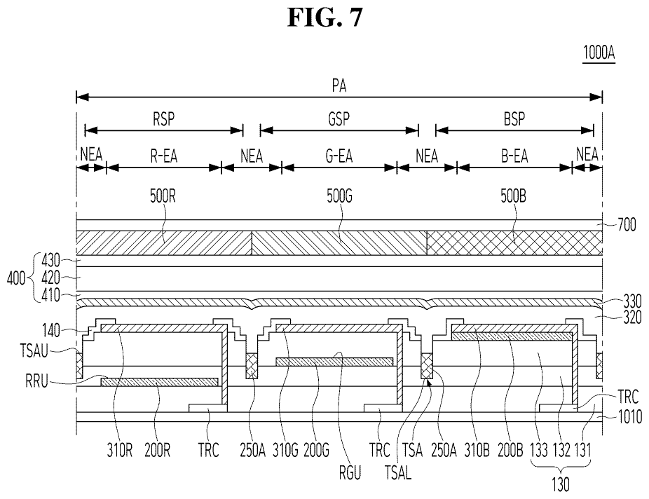

FIGS. 7 to 9 show cross-sections taken in an order of the red sub-pixel, the green sub-pixel, and the blue sub-pixel of FIG. 3 according to an embodiment of the present disclosure.

FIG. 7 is a cross-sectional view showing a light emitting display device according to a second embodiment of the present disclosure.

As shown in FIG. 7, in the light emitting display device according to the other embodiment of the present disclosure, anodes 310R, 310G, and 310B of a light emitting element 300 are connected to connectors TRC of second transistors in respective sub-pixels RSP, GSP, and BSP, respectively.

The connector TRC of each second transistor shown in FIG. 7 has a shape from which a gate electrode and a first source/drain electrode are omitted and, as such, shows only a portion of the second source/drain electrode of FIG. 4. The connector TRC of each second transistor may be disposed on the element substrate 1010 described with reference to FIG. 4.

As shown in FIG. 7, the light emitting display device according to the embodiment of the present disclosure, which is designated by reference numeral “1000A”, includes a red sub-pixel RSP, a green sub-pixel GSP, and a blue sub-pixel BSP.

The light emitting element 300 may include first to third anodes 310R, 310G, and 310B in the red sub-pixel RSP, the green sub-pixel GSP, and the blue sub-pixel BSP. A reflective electrode may include first to third reflective electrodes 200R, 200G, and 200B having different vertical distances from the first to third anodes 310R, 310G, and 310B at the red sub-pixel RSP, the green sub-pixel GSP, and the blue sub-pixel BSP, respectively.

In the light emitting display device 1000A of FIG. 7, trenches TSA among the sub-pixels RSP, GSP, and BSP may have the same or substantially same shape, and heights of a light shielding material layer 250A filling the trenches TSA may be equal.

A lower surface TSAL of each trench TSA may be disposed at a level not higher than an upper surface RRU of the first reflective electrode 200R which has a lowest vertical phase among the reflective electrodes. That is, the lower surface TSAL of each trench TSA may have the same or substantially same vertical phase as that of the upper surface RRU of the first reflective electrode 200R or may be disposed at a level lower than the upper surface RRU of the first reflective electrode 200R.

In addition, in the light emitting display device 1000A of FIG. 7, an upper surface TSAU of the light shielding material layer 250A may have the same phase or substantially the same phase as that of an upper surface RGU of the second reflective electrode 200G or may be disposed at a level higher than the upper surface RGU of the second reflective electrode 200G. This is because the light shielding material layer 250A should prevent light emitted from a particular one of the sub-pixels RSP, GSP, and BSP from being transmitted to another sub-pixel adjacent to the particular sub-pixel. Light directed downwards from emission areas R-EA, G-EA, and B-EA may be directly blocked by the reflective electrodes 200R, 200G, and 200B, respectively. In addition, when light generated from the light emitting element in a particular sub-pixel is inclinedly directed downwards, the light shielding material layer 250A disposed at a level not lower than the upper surface RGU of the second reflective electrode 200G disposed on a second insulating layer 132 may block the laterally-moving light.

Meanwhile, when the upper surface of the light shielding material layer 250A has a vertical phase lower than that of the third reflective electrode 200B, an intermediate layer 320 may be easily divided in areas corresponding to the trenches TS by virtue of steps formed in the areas corresponding to the trenches TS. In this case, there is an effect of more reliably achieving reduction of prevention of leakage current between the adjacent sub-pixels.

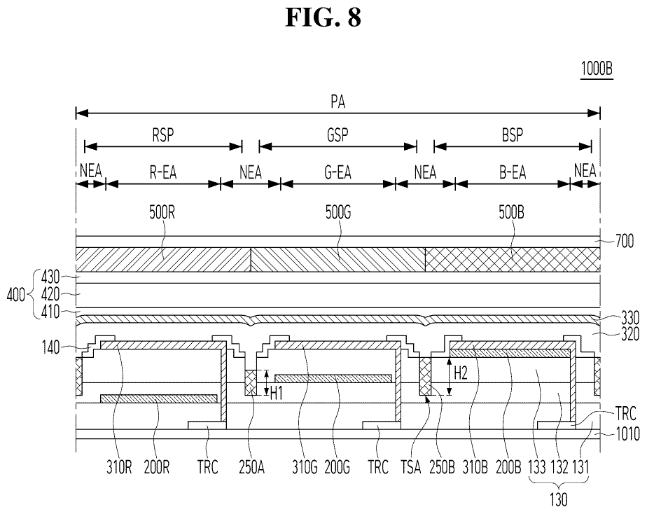

FIG. 8 is a cross-sectional view showing a light emitting display device according to a third embodiment of the present disclosure.

As shown in FIG. 8, in the light emitting display device according to the third embodiment of the present disclosure, which is designated by reference numeral “1000B”, the height of a first light shielding material layer 250A disposed between a red sub-pixel RSP and a green sub-pixel GSP is different from the height of a second light shielding material layer 250B disposed around a blue sub-pixel BSP.

The blue sub-pixel BSP includes a third reflective electrode 200B having a relatively high vertical phase.

On the other hand, the red sub-pixel RSP includes a first reflective electrode 200R disposed at a lowest level among reflective electrodes. The green sub-pixel GSP includes a second reflective electrode 200G having a vertical phase between those of the first reflective electrode 200R and the third reflective electrode 200B.

In this case, the first light shielding material layer 250A fills a trench TSA between the first reflective electrode 200R and the second reflective electrode 200G such that the first light shielding material layer 250A has an upper surface disposed below an upper surface of the trench TSA. The first light shielding material layer 250A has the same lower surfaces or substantially same surfaces as that of the trench TSA, and the lower surface of the trench TSA is disposed at a level not higher than an upper surface of the first reflective electrode 200R.

The third reflective electrode 200B has a vertical phase higher than those of the first and second reflective electrodes 200R and 200G disposed therearound. In order to block lateral leakage light inclinedly emitted in the blue sub-pixel BSP, an upper surface of a second light shielding material layer 250B filling a trench TSA disposed around the third reflective electrode 200B may be disposed to be closer to the third reflective electrode 200B. Accordingly, the upper surface of the second light shielding material layer 250B may be disposed at a level higher than the upper surface of the first light shielding material layer 250A and, as such, a second height H2 of the second light shielding material layer 250B may be greater than a first height H1 of the first light shielding material layer 250A.

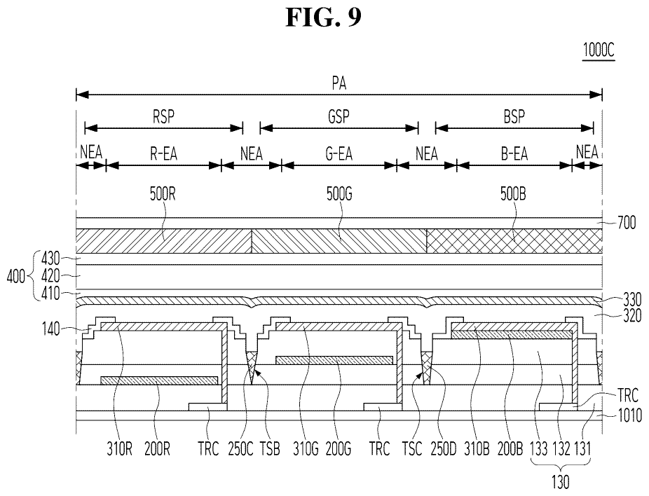

FIG. 9 is a cross-sectional view showing a light emitting display device according to a fourth embodiment of the present disclosure.

As shown in FIG. 9, in the light emitting display device according to the fourth embodiment of the present disclosure, which is designated by reference numeral “1000C”, shapes of first and second trenches TSB and TSC disposed among adjacent ones of sub-pixels RSP, GSP, and BSP are different from each other. Although the trenches TSB and TSC among the adjacent sub-pixels RSP, GSP, and BSP have different shapes, it may be possible to obtain the same effect of reducing or preventing lateral leakage current directed downwards from each sub-pixel.

The first trench TSB and the second trench TSC shown in FIG. 9 have, in common, a shape having a width gradually reduced while extending toward a lower surface of a planarization layer 130. When light directed downwards from each of emission areas R-EA, G-EA, and B-EA of a light emitting element 300 is blocked at an upper side, the light is no longer transmitted to a lower side. Accordingly, each trench may be formed such that the width of an upper portion thereof is greater than that of a lower portion thereof.

As shown in FIG. 9, the trenches TSB and TSC may have an inverted triangular shape or a trapezoidal shape at portions thereof filled with light shielding material layers 250C and 250D, respectively. However, the light emitting display device according to the embodiment of the present disclosure is not limited to the disposition of FIG. 9. Although FIG. 9 shows an example in which the first trench TSB having an inverted triangular shape is disposed between the red sub-pixel RSP and the green sub-pixel GSP, and the second trench TSC having a trapezoidal shape is disposed between the green sub-pixel GSP and the blue sub-pixel BSP, the first trench TSB may be disposed around the blue sub-pixel BSP, or the second trench TSC may be disposed around the red sub-pixel RSP.

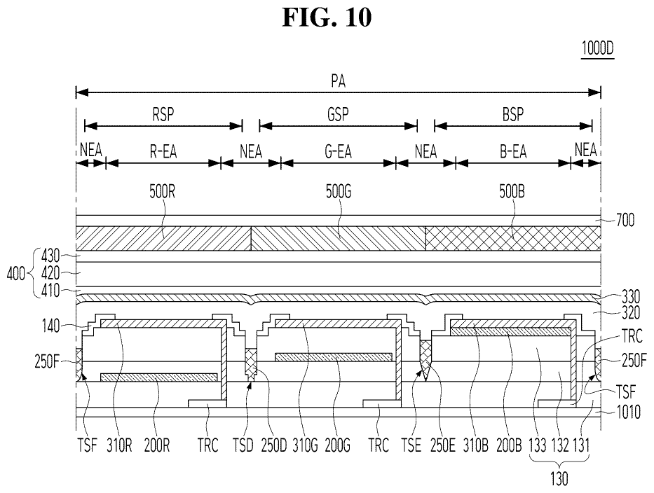

FIG. 10 is a cross-sectional view showing a light emitting display device according to a fifth embodiment of the present disclosure.

As shown in FIG. 10, in the light emitting display device according to the fifth embodiment of the present disclosure, which is designated by reference numeral “1000D”, trenches TSD, TSE, and TSF disposed among adjacent ones of sub-pixels RSP, GSP, and BSP have different shapes, respectively.

The first trench TSD, the second trench TSE, and the third trench TSF have different lower structures disposed in a second insulating layer 132. The first trench TSD has a structure having a relatively small width at a predetermined depth near a lower surface of the second insulating layer 132. The second trench TSE has a shape gradually narrowed while extending from an upper surface to a lower surface of the second insulating layer 132 and, as such, forming a point contact upon contacting the lower surface of the second insulating layer 132. The third trench TSF has a shape gradually narrowed while extending toward the lower surface of the second insulating layer 132 to have a round shape and, as such, forming a point contact upon contacting the lower surface of the second insulating layer 132.

The shape of each of the first to third trenches TSD, TSE, and TSF is illustrated as having different structures at upper and lower portions thereof. However, embodiments of the present disclosure are not limited to the above-described condition. The configuration in which each trench structurally has a smaller width at a lower portion thereof than at an upper portion thereof is realizable in terms of process.

In addition, among first to third light shielding material layers 250D, 250E, and 250F respectively filling the first to third trenches TSD, TSE, and TSF, the second light shielding material layer 250E and the third light shielding material layer 250F disposed closer to the blue sub-pixel BSP may have upper surfaces disposed at a higher level and, as such, lateral leakage of light inclinedly passing through a third anode 310B may be more effectively reduced or prevented.

The light emitting display device according to each embodiment of the present disclosure is intended to prevent or at least reduce light generated from a light emitting element from influencing a lower driving circuit.

The light emitting display device according to each embodiment of the present disclosure has an ultra-high resolution structure in which sub-pixels are densely disposed in a limited area. In addition, in the light emitting display device, the size of individual emission areas may be reduced, thereby reducing an area of a driving circuit connected to the individual emission area. Accordingly, it may be possible to reduce power consumption and to enable low-power driving. In this regard, implementation of a light emitting display device having high-efficiency and high-resolution characteristics may be achieved.

The light emitting display device according to each embodiment of the present disclosure includes a trench among sub-pixels, thereby preventing or at least reducing generation of leakage current between adjacent ones of the sub-pixels. In addition, a light shielding material layer fills the interior of the trench and, as such, it may be possible to structurally block light laterally transferred between the adjacent sub-pixels.

The light emitting display device according to each embodiment of the present disclosure includes a light shielding material layer structurally provided between adjacent sub-pixels and, as such, it may be possible to not only prevent transistors configured to be driven by low power from being driven by a leakage current generated due to leakage light between the adjacent sub-pixels, but also to achieve an enhancement in optical reliability of driving circuits.

The light emitting display device according to each embodiment of the present disclosure may prevent influence between adjacent sub-pixels caused by light emitted from the sub-pixels and, as such, stable low-grayscale expression may be achieved.

The light emitting display device according to each embodiment of the present disclosure may have effects of reduced power consumption, high efficiency, and high luminance, thereby having sustainability. Thus, environmental/social/governance (ESG) goals may be achieved.

A light emitting display device according to one embodiment of the present disclosure may comprise a substrate comprising a plurality of sub-pixels, a driving circuit at each of the plurality of sub-pixels, an insulating layer on the driving circuit, a reflective electrode at each of the plurality of sub-pixels in the insulating layer, a trench at adjacent two sub-pixels among the plurality of sub-pixels in the insulating layer, a light shielding material layer filling the trench and a light emitting element on the insulating layer.

In a light emitting display device according to one embodiment of the present disclosure, the plurality of sub-pixels may comprise a red sub-pixel, a green sub-pixel, and a blue sub-pixel, the light emitting element may comprise first to third anodes respectively corresponding to the red sub-pixel, the green sub-pixel, and the blue sub-pixel and the reflective electrodes may comprise first to third reflective electrodes having different vertical distances from the first to third anodes at the red sub-pixel, the green sub-pixel, and the blue sub-pixel, respectively.

In a light emitting display device according to one embodiment of the present disclosure, among the first to third reflective electrodes, the first reflective electrode may be disposed at a lowest level and the third reflective electrode is disposed at a highest level and at least a portion of the light shielding material layer may have an upper surface between a vertical phase of the second reflective electrode and a vertical phase of the third reflective electrode.

In a light emitting display device according to one embodiment of the present disclosure, a lower surface of the trench may be disposed at a level not higher than an upper surface of the first reflective electrode.

In a light emitting display device according to one embodiment of the present disclosure, the upper surface of the light shielding material layer may be disposed at a level not lower than an upper surface of the second reflective electrode.

In a light emitting display device according to one embodiment of the present disclosure, the light shielding material layer may comprise a first light shielding material layer disposed between the red sub-pixel and the green sub-pixel, and a second light shielding material layer disposed between the blue sub-pixel and another sub-pixel different from the blue sub-pixel. The second light shielding material layer may be thicker than the first light shielding material layer.

In a light emitting display device according to one embodiment of the present disclosure, the light shielding material layer may comprise an organic insulating material.

In a light emitting display device according to one embodiment of the present disclosure, the trench may have a smaller width at a lower surface thereof than at an upper surface thereof.

In a light emitting display device according to one embodiment of the present disclosure, each of the plurality of sub-pixels may further comprise a fence overlapping with an edge of an anode of the light emitting element. The fence may be disposed on the insulating layer.

In a light emitting display device according to one embodiment of the present disclosure, the light shielding material layer may be spaced apart from the fence and the anode of the light emitting element.

In a light emitting display device according to one embodiment of the present disclosure, the light shielding material may contact the fence.

In a light emitting display device according to one embodiment of the present disclosure, the trench may surround an anode of the light emitting element

In a light emitting display device according to one embodiment of the present disclosure, the driving circuit may comprise at least one transistor. The at least one transistor may comprises a first source drain region and a second source drain region provided at the substrate comprising silicon, a gate electrode disposed on the substrate between the first source drain region and the second source drain region and a first source drain electrode and a second source drain electrode respectively disposed at opposite sides of the gate electrode while being connected to the first source drain region and the second source drain region, respectively.

Although the preferred embodiments of the present disclosure have been disclosed for illustrative purposes, those skilled in the art will appreciate that various modifications, additions and substitutions are possible, without departing from the scope and spirit of the disclosure as disclosed in the accompanying claims.

What is claimed is:

1. A light emitting display device comprising:
a substrate comprising a plurality of sub-pixels;
a driving circuit at each of the plurality of sub-pixels;
an insulating layer on the driving circuit;
a reflective electrode at each of the plurality of sub-pixels in the insulating layer;
a trench at adjacent two sub-pixels among the plurality of sub-pixels in the insulating layer;
a light shielding material layer that fills the trench; and
a light emitting element on the insulating layer.

2. The light emitting display device according to claim 1, wherein:
the plurality of sub-pixels comprises a red sub-pixel, a green sub-pixel, and a blue sub-pixel;
the light emitting element comprises a first anode, a second anode, and a third anode respectively corresponding to the red sub-pixel, the green sub-pixel, and the blue sub-pixel; and
the reflective electrode comprises a first reflective electrode, a second reflective electrode, and a third reflective electrode having different vertical distances from the first anode, the second anode, and the third anode at the red sub-pixel, the green sub-pixel, and the blue sub-pixel, respectively.

3. The light emitting display device according to claim 2, wherein:
among the first reflective electrode, the second reflective electrode, and the third reflective electrode, the first reflective electrode is at a lowest level and the third reflective electrode is at a highest level; and
at least a portion of the light shielding material layer has an upper surface between a vertical phase of the second reflective electrode and a vertical phase of the third reflective electrode.

4. The light emitting display device according to claim 3, wherein a lower surface of the trench is at a level not higher than an upper surface of the first reflective electrode.

5. The light emitting display device according to claim 3, wherein the upper surface of the light shielding material layer is at a level not lower than an upper surface of the second reflective electrode.

6. The light emitting display device according to claim 1, wherein:
the plurality of sub-pixels comprises a red sub-pixel, a green sub-pixel, and a blue sub-pixel;
the light shielding material layer comprises a first light shielding material layer between the red sub-pixel and the green sub-pixel, and a second light shielding material layer between the blue sub-pixel and another sub-pixel different from the blue sub-pixel; and
the second light shielding material layer is thicker than the first light shielding material layer.

7. The light emitting display device according to claim 1, wherein the light shielding material layer comprises an organic insulating material.

8. The light emitting display device according to claim 1, wherein the trench has a width of a lower surface of the trench is less than a width of an upper surface of the trench.

9. The light emitting display device according to claim 1, wherein:
each of the plurality of sub-pixels further comprises a fence overlapping with an edge of an anode of the light emitting element and the fence is on the insulating layer.

10. The light emitting display device according to claim 9, wherein the light shielding material layer is spaced apart from the fence and the anode of the light emitting element.

11. The light emitting display device according to claim 9, wherein the light shielding material layer contacts the fence.

12. The light emitting display device according to claim 1, wherein the trench surrounds an anode of the light emitting element.

13. The light emitting display device according to claim 1, wherein the driving circuit comprises at least one transistor, the at least one transistor comprising:
a first source drain region and a second source drain region at the substrate comprising silicon;
a gate electrode on the substrate between the first source drain region and the second source drain region; and
a first source drain electrode and a second source drain electrode respectively disposed at opposite sides of the gate electrode while being connected to the first source drain region and the second source drain region, respectively.
